(19) United States
(12) Patent Application Publication
(10) Pub. No.: US 2025/0021006 A1
(43) Pub. Date: Jan. 16, 2025

(54) Wafer Bow Mitigation

(71) Applicants: Tokyo Electron Limited, Tokyo (JP); The University of Queensland, Brisbane (AU)

(72) Inventors: Andrew Whittaker, Toowong (AU); Idriss Blakey, Mansfield (AU); Md Daloar Hossain, St. Lucia (AU); Hui Peng, Toowong (AU); Charlotte Cutler, Albany, NY (US)

(21) Appl. No.: 18/350,480

(22) Filed: Jul. 11, 2023

(51) Int. Cl. G03F 7/20; G03F 7/025; G03F 7/16

(52) U.S. Cl. CPC G03F 7/2022; G03F 7/025; G03F 7/162

(57) ABSTRACT

A method of processing a substrate that includes: depositing first and second monomers over a substrate, the first monomer being a first type of monomer and the second monomer being a second type of monomer different from the first type of monomer; exposing the substrate to a first actinic radiation to induce a polymerization of the first and second monomers over the substrate, where, after the polymerization, the substrate has a bow with a first curvature; and exposing the substrate to a second actinic radiation to induce a rearrangement of the polymer, the rearrangement reducing the bow.

### TECHNICAL FIELD

The present invention relates generally to method of processing a substrate and, in particular embodiments, to wafer bow mitigation.

### BACKGROUND

Semiconductor fabrication involves multiple varied steps and processes. One typical fabrication process is known as photolithography. Photolithography uses radiation, such as ultraviolet or visible light, to generate fine patterns in a semiconductor device design. Many types of semiconductor devices, such as diodes, transistors, and integrated circuits, can be constructed using semiconductor fabrication techniques including photolithography, etching, film deposition, surface cleaning, metallization, and so forth.

Exposure systems (also called tools) are used to implement photolithographic techniques. An exposure system typically includes an illumination system, a reticle (also called a photomask) or spatial light modulator (SLM) for creating a circuit pattern, a projection system, and a wafer alignment stage for aligning a photosensitive resist-covered semiconductor wafer. The illumination system illuminates a region of the reticle or SLM with a preferably rectangular slot illumination field. The projection system projects an image of the illuminated region of the reticle pattern onto the wafer. For accurate projection, it is important to expose a pattern of light on a wafer that is relatively flat or planar, preferably having less than 10 microns of height deviation. Thus, a method for correcting wafer bow is desired.

### SUMMARY

In accordance with an embodiment of the present invention, a method of processing a substrate that includes: depositing first and second monomers over a substrate, the first monomer being a first type of monomer and the second monomer being a second type of monomer different from the first type of monomer; exposing the substrate to a first actinic radiation to induce a polymerization of the first and second monomers over the substrate, where, after the polymerization, the substrate has a bow with a first curvature; and exposing the substrate to a second actinic radiation to induce a rearrangement of the polymer, the rearrangement reducing the bow.

In accordance with an embodiment of the present invention, a method of processing a substrate that includes: spin coating a film over a substrate including a major working surface having a semiconductor device structure and a backside surface opposite the major working surface, the film being coated over the backside surface, where, prior to the spin coating, the substrate has an initial bow with a first curvature; exposing the backside surface of the substrate to a pattern of a first actinic radiation; and after the exposure to the pattern of the first actinic radiation, exposing the backside surface of the substrate to a pattern of a second actinic radiation with a wavelength shorter than that of the first actinic radiation, where, after the exposure to the pattern of the second actinic radiation, the substrate has a bow with a second curvature less than the first curvature.

In accordance with an embodiment of the present invention, a method of processing a substrate that includes: depositing a film over a substrate, the film including an alkyne and a thiol, where, prior to depositing the film, the substrate has an initial bow with a first curvature; polymerizing the film via a thiol-yne reaction to form a polymer by exposing the substrate to a pattern of visible light, where, after polymerizing the film, the substrate has an intermediate bow with a second curvature different from the first curvature; and rearranging a portion of the polymer via a thiol-thioester exchange reaction by exposing the substrate to a pattern of ultraviolet (UV) light, the rearranging the portion of the polymer reducing the intermediate bow.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates substrates with various types and severities of wafer bow;

FIGS. 2A-2D illustrate cross-sectional views of an example substrate at various stages during a semiconductor device fabrication process in accordance with various embodiments, wherein FIG. 2A illustrates the substrate comprising a device structure on a working surface, FIG. 2B illustrates the substrate with a bow mitigation stress film formed on the backside of the substrate, FIG. 2C illustrates the substrate during an exposure to a pattern of a first actinic radiation, and FIG. 2D illustrates the substrate during an exposure to a pattern of a second actinic radiation;

FIGS. 3A-3C illustrate cross-sectional views of an example substrate during a bow test with stress release mechanism in accordance with various embodiments, wherein FIG. 3A illustrates the substrate with a bow mitigation stress film, FIG. 3B illustrates the substrate after crosslinking to cause a primary bow, and FIG. 3C illustrates the substrate after stress release;

FIG. 4 illustrates an example alkyne used as a monomer for stress film formation in accordance with an embodiment;

FIG. 5 illustrates an example thiol used as a monomer for stress film formation in accordance with an embodiment;

FIG. 6 illustrates a formation of an example bow mitigation stress film via thiol-yne reaction in accordance with an embodiment;

FIG. 7 illustrates a mechanism of an example rearrangement of a polymer structure for a bow mitigation stress film;

FIGS. 8A-8C illustrate experimental results for bow mitigation with tuning ability in accordance with an embodiment, wherein FIG. 8A illustrates a surface height profile of a substrate with a spin-on stress film after an initial visible light exposure, FIG. 8B illustrates a surface height profile of the same substrate after the initial visible light exposure and a subsequent ultraviolet (UV) light exposure, and FIG. 8C illustrates a surface height profile of the same substrate after the initial visible light exposure, the subsequent UV light exposure, and a base exposure for relaxation;

FIGS. 9A-9C illustrate process flow charts of methods of forming a stress film in accordance with various embodiments, wherein FIG. 9A illustrates an embodiment, FIG. 9B illustrates another embodiment, and FIG. 9C illustrates yet another embodiment; and

FIG. 10 illustrates a block diagram of an example coater for stress film formation in accordance with an embodiment.

### DETAILED DESCRIPTION OF ILLUSTRATIVE EMBODIMENTS

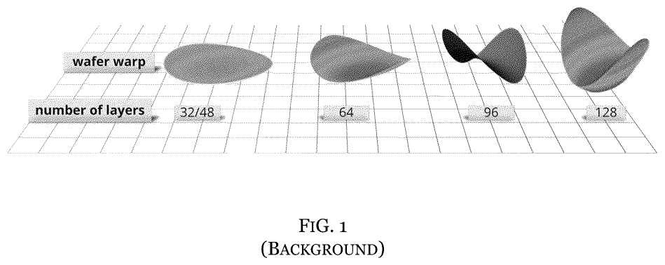

This application relates to a method of processing a substrate, more particularly to bow mitigation stress film (referred to as stress film in this disclosure) that can mitigate the wafer bow. In the fabrication of 3D NAND memory devices, the device structures can extend vertically away from a working surface of a wafer. For example, 128 layers can be used for 3D NAND devices on a 300 mm wafer. As more and more memory is being stored on these devices, the devices become heavier. A defect in an underlying, earlier layer can be magnified to cause severe bow with later layers. FIG. 1 shows the systematic increase in the number of layers in the front side 3D NAND stack results in further wafer bow and increases the severity of the problem. This can cause issues including non-uniformities, non-planarity, overlay mis-match for lithography or other processes, and wafer handling degradation. Therefore, techniques for correcting wafer bow are desired and use of a bow mitigation stress film (stress film) is among them.

Some mitigation strategies include depositing silicon nitride films on the backside of the wafer via, for example, chemical vapor deposition (CVD), which can cause a large amount of stress on the wafer and the devices. Then, predetermined portions of the silicon nitride can be imaged, illuminated, or exposed, and subsequently removed, alleviating the stress in certain points on the wafer, hence re-shaping the wafer in a different manner. The problem introduced via the silicon nitride film method is that the method requires different tooling, which can mean a simple track-based process may be incompatible, and thus it can require loading the wafers into an entirely different tool. Furthermore, the method can also be time-consuming to put the desired amount of silicon nitride on the back of the wafers. Additionally, the method is generally a very complex process to image the silicon nitride films or to tune the patterns in the silicon nitride film to alleviate the bow of the water, and it is not possible to achieve secondary or higher order bow correction or local bow correction.

A spin-on, direct write, tunable stress film can be used as an alternative to CVD-silicon nitride film to overcome the issue of tooling. The film can be coated using a coater-developer tool (also known as a track tool). The direct write process is able to induce crosslinking or additional polymerization, which can build up stress in the film. The built up stress in the film may allow wafer bow correction both globally and to some extent locally. However, the tuning the stress of the film have been so far irreversible in that only stress build up for the stress film is possible. There has been no stress film that may release the built up stress in the film. To enable more advanced tuning of the stress film and secondary or higher order bow correction, further improvement of spin-on stress film is therefore desired.

Various embodiments of the stress film described in this disclosure may be a polymer-based film with a unique capability of rearrangement for stress release in addition to crosslinking for stress build up. Crosslinking of monomer building blocks, such as thiol-yne reaction, can be used to form a polymer stress film with stress built up within the polymer stress film. This built up stress in the stress film may be controllably released by a rearrangement mechanism, such as thiol-thioester exchange reaction. The crosslinking and rearrangement may be tuned individually by separate actinic radiation exposures: for example, first visible light exposure for crosslinking and second UV exposure for rearrangement. Using these stress films possessing two different mechanism for structural changes, wafer bow correction processes may be improved with a greater degree of tunability. In addition, in various embodiments, the initial crosslinking may also be turned by adjusting the conditions for actinic radiation exposures.

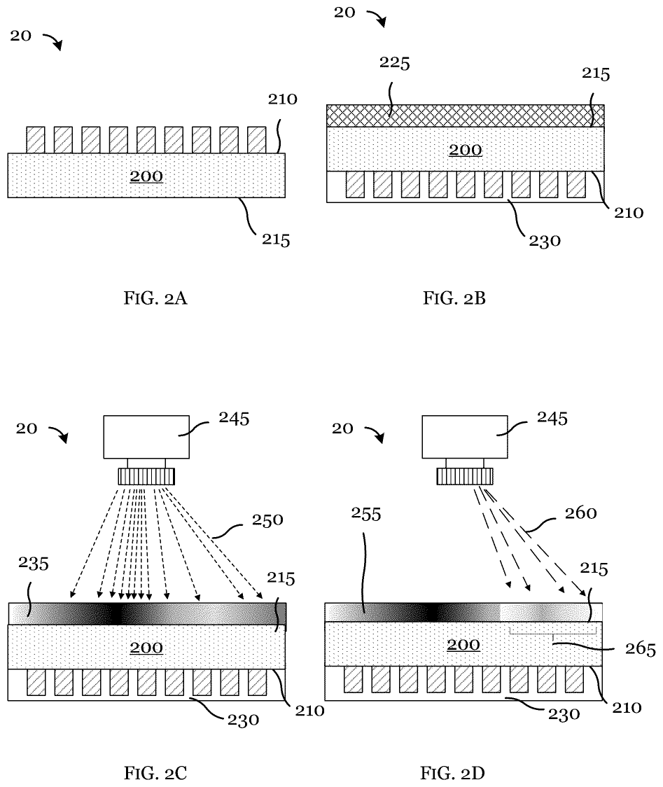

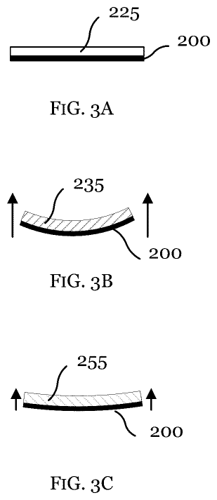

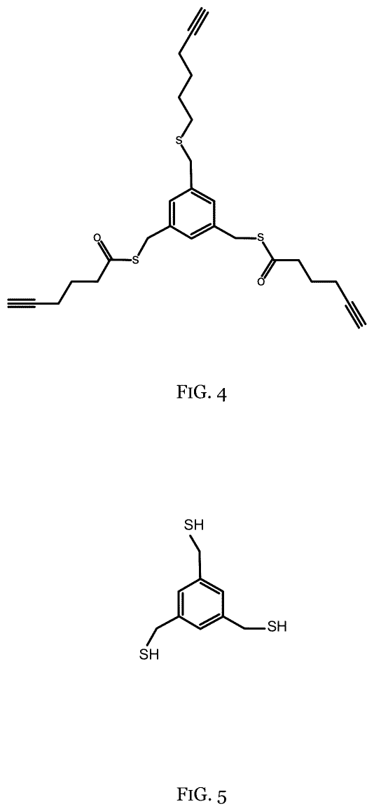

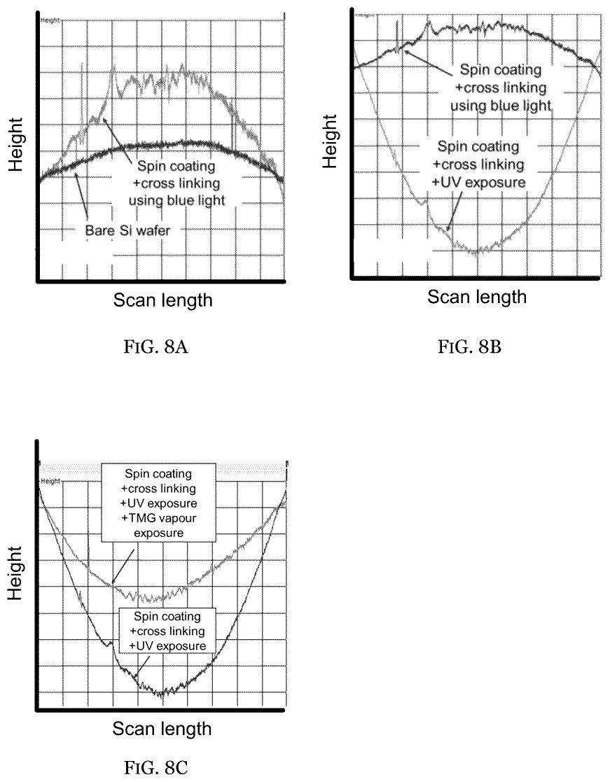

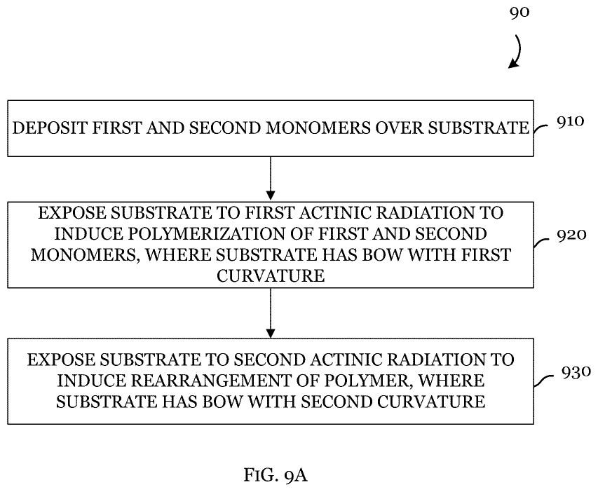

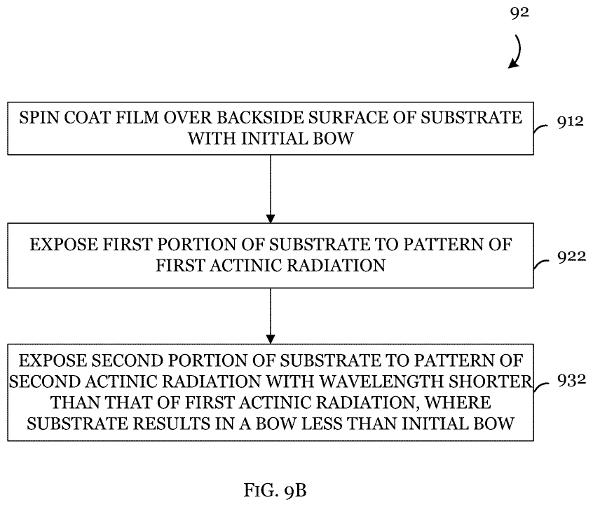

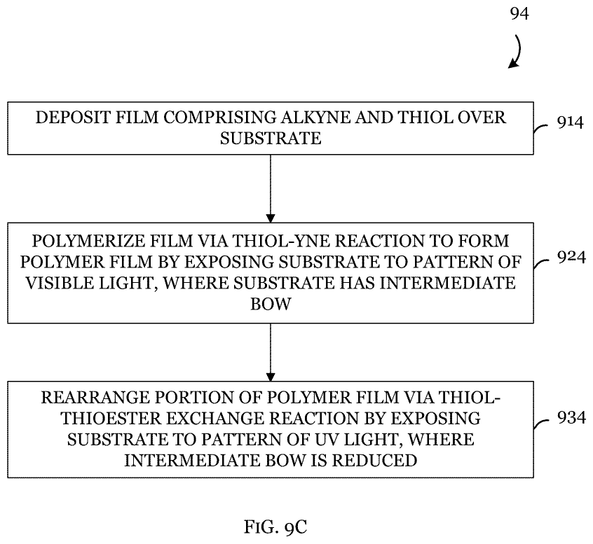

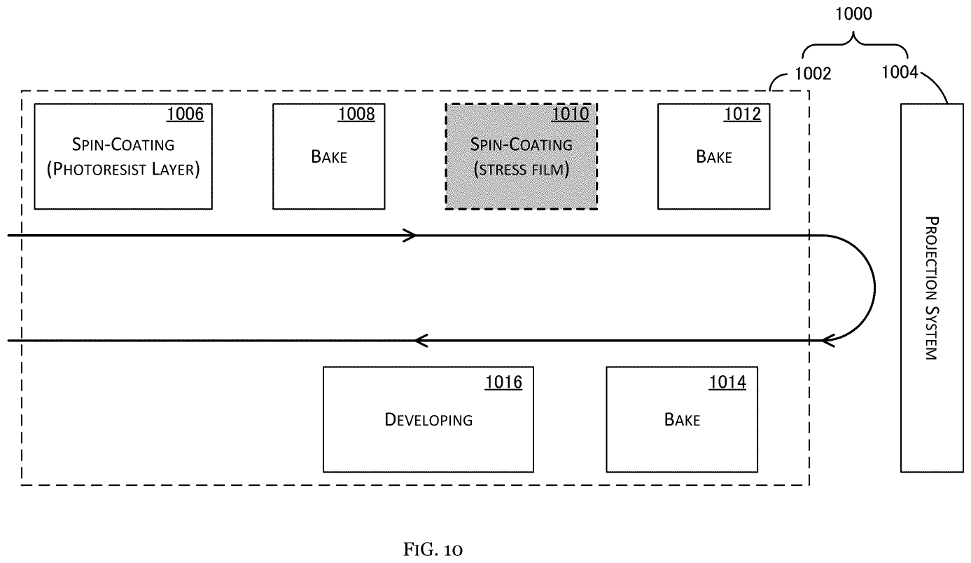

In the following, steps of tunable stress film formation over a substrate are described referring to FIGS. 2A-2D in accordance with various embodiments, along with an example bow mitigation illustrated in FIGS. 3A-3C. Example chemical compositions and structures for film precursors and polymer film are then illustrated in FIGS. 4-7. Representative experimental data for bow mitigation test using a stress film in accordance with one embodiment are illustrated in FIGS. 8A-8C. Example process flow diagrams for polymer stress film formation are illustrated in FIG. 9A-9C. An example coater system for stress film formation is illustrated in FIG. 10. All figures in this disclosure are drawn for illustration purpose only and not to scale, including the aspect ratios of features.

FIGS. 2A-2D illustrate cross-sectional views of an example substrate 200 at various stages during a semiconductor device fabrication process in accordance with various embodiments. Although the substrate 200 is illustrated as flat in FIGS. 2A-2D, it may be bowed, warped, or having a curvature, which may be corrected with a bow mitigation stress film as described below.

FIGS. 3A-3C illustrate cross-sectional views of an example substrate 200 during a bow test with stress release mechanism in accordance with various embodiments.

FIG. 2A illustrates a cross-sectional view of an incoming substrate 200 comprising a device structure 20 on a working surface 210. In various embodiments, the substrate 200 may be a part of, or including, a semiconductor device, and may have undergone a number of steps of processing following, for example, a conventional process. The substrate 200 accordingly may comprise layers of semiconductors useful in various microelectronics. For example, the semiconductor structure may comprise the substrate 200 in which various device regions are formed.

In one or more embodiments, the substrate 200 may be a silicon wafer, or a silicon-on-insulator (SOI) wafer. In certain embodiments, the substrate 200 may comprise a silicon germanium wafer, silicon carbide wafer, gallium arsenide wafer, gallium nitride wafer and other compound semiconductors. In other embodiments, the substrate 200 comprises heterogeneous layers such as silicon germanium on silicon, gallium nitride on silicon, silicon carbon on silicon, as well layers of silicon on a silicon or SOI substrate. In various embodiments, the substrate 200 is patterned or embedded in other components of the semiconductor device.

As illustrated in FIG. 2A, the substrate 200 may comprise the working surface 210 and a backside surface 215. The working surface 210 of the substrate 200 can be the surface where the target devices are fabricated. The device structure 20 can be active devices or partially formed active devices such as transistors or memory cells. The pattern of the device structure 20 illustrated in FIG. 2A is only for illustration and any patterns that may be useful for the devices may be present. For the purpose of stress film formation, the substrate 200 can be received in a deposition tool, for example, a coating module of a coater-developer tool or other track-based tool.

In various embodiments, due to the presence of the device structure 20 and the impact of already performed fabrication processes, there may be an imbalance of stress between on the working surface 210 and the backside surface 215. In some cases, the imbalance of stress may have caused a wafer bow at any stage of the fabrication, resulting in the substrate 200 that is bowed or warped (e.g., FIG. 1). Therefore, it can be desired to mitigate this imbalance of stress or correct the bow or warp by, for example, using a bow mitigation stress film as further described below. In this disclosure, bow is used for any curvature including warp, and the term bow mitigation is used to refer any process to reduce the imbalance of stress of the substrate or correct any existing curvature (e.g., bow and/or warp) of the substrate regardless of the imbalance of stress. In other words, bow mitigation may flatten a curved surface or exert a force on any surface to increase the stiffness (e.g., Young's modulus).

FIG. 2B illustrates a cross-sectional view of the substrate 200 with a tunable stress film 225 formed on the backside surface 215 of the substrate 200.

Prior to performing subsequent fabrication processes on the substrate 200 illustrated in FIG. 2A, a bow mitigation stress film (stress film) may be deposited on a surface of the substrate 200 to mitigate the bow stress that may be present. In various embodiments, the stress film may be applied on the backside surface 215 of the substrate 200 to reduce the degree of bowing of the substrate 200 or reduce the imbalance of stress between on the working surface 210 and the backside surface 215.

In various embodiments, as illustrated in FIG. 2B, the substrate 200 may be flipped and the tunable stress film 225 can be formed on the backside surface 215. In certain embodiments, however, the substrate 200 may not need to be flipped. For example, the processing tool can include systems for vertically upward directed coating, spraying, or deposition. That is, the substrate 200 can continue on the track and the processing tool can form the tunable stress film 225 on the backside surface 215 by spray coating.

The tunable stress film 225 may comprise a polymer that may be further crosslinked and rearranged with under external stimulus in subsequent steps. In various embodiments, the tunable stress film 225 may comprise a polymer having thioester and thiol groups. Chemical compositions of monomers and the polymer for the tunable stress film 225 are further described referring to FIGS. 4-6.

The tunable stress film 225 may be formed using a solution-based process such as spin-on process from a film precursor solution. Accordingly, the method of stress film formation may comprise preparing the film precursor solution by dissolving film precursors, and forming a film from the film precursor solution. In various embodiments, the film may be baked to remove the solvent from the film. Solubility and stability of the precursor and intermediate may be modulated by polymer structure and functionalization. Examples of solvent for spin-on process may include propylene glycol methyl ether (PGME) and propylene glycol methyl ether acetate (PGMEA).

The use of spin-on or other solution-based process for stress film formation may advantageously reduce the number and cost of steps for wafer bow mitigation, compared to CVD SiN film deposition approach, because unlike CVD, the tunable stress film may be deposited using a deposition module of a common track system (FIG. 10).

Further illustrated in FIG. 2B, in one or more embodiments, a protective fill or protective film 230 may be deposited for the device structure 20 on the working surface 210. In addition to, or in place of, the protective film 230, a carrier wafer may be attached to facilitate handling of the substrate 200.

It should be noted that the working surface 210 and the backside surface 215 are used herein to label opposing sides of the substrate 200. In some microfabrication processes, a given wafer can have active devices or power delivery structures formed on both sides. In this case, the working surface 210, the backside surface 215, or both may receive the tunable stress film 225 depending on fabrication process stage.

In various embodiments, exposures to actinic radiation may be used to induce the crosslinking or other chemical reactions of the film precursor for the stress film formation (e.g., the tunable stress film 225 in FIG. 2B). Accordingly, to initiate and facilitate the formation of polymer network, the film precursor may comprise a photo-responsive agent or additive, such as photo acid generators, thermal acid generators, photo initiators, and photo destructive bases. In one or more embodiments, the film precursor may comprise a free radical photo initiator based on the hexaaryl-bisimidazolyl (HABI) molecule, and 2-(2-nitrophenyl)-propyloxycarbonyl/tetramethylguanidine (NPPOC-TMG) as a photo-base. In certain embodiments, the tunable stress film 225 may also comprise, in addition to the monomer, partially condensed intermediates.

FIG. 2C illustrates a cross-sectional view of the substrate 200 during an exposure to a pattern of a first actinic radiation.

In various embodiments, the tunable stress film 225 of FIG. 2B may be exposed to a pattern of a first actinic radiation 250 to induce chemical reaction such as crosslinking to induce or improve the bow modification capability of the film globally or locally. The stress film after the exposure to the first actinic radiation 250 is herein referred to as a stressed film 235 to indicate some structural/chemical change from the initial state of the stress film. However, in certain embodiments, the change induced within the film may be small and the stressed film 235 after the first actinic radiation exposure may not be bent or deformed substantially relative to the tunable stress film 225. This pattern of actinic radiation may define a first stress modification pattern for the film.

In FIGS. 3A and 3B, the effect of the first exposure step is illustrated in a simple bow test. The substrate 200 having a tunable stress film 225 (FIG. 3A) may be exposed to the pattern of the first actinic radiation for crosslinking to form a stressed film 235 (FIG. 3B). The crosslinking may induce a structural change in the film causing the film to exert a force indicated by arrows in FIG. 3B and a stress builds up in the film. As a result, upon the exposure, if enough stress is built up in the film, the stressed film 235 may cause a primary bow and the substrate 200 may bend. The substrate 200 in FIGS. 2A-2D and 3A is illustrated as a flat substrate, but as described above, various semiconductor device fabrication processes result in a substrate with a bow or warp, which requires a correction to improve the planarity of the substrate before proceeding to subsequent processes. Accordingly, in various embodiments, the ability of the stressed film 235 to cause the primary bow may be used to flatten a working substrate that has an initial bow.

In various embodiments, prior to forming a stress film or any exposure step, wafer bow measurement may be performed to obtain spatial information of the bowing of the substrate 200. This spatial information may be used to determine the pattern of actinic radiation and local bow mitigation can be achieved. Wafer bow measurement may be repeatedly performed the effect of applying the stress film and based on the measurement results, the steps of film formation and exposure to actinic radiation may be repeated or its recipe may be updated.

Various lithography tools can be used for the exposure step. In various embodiments, a direct-write laser or lithography tool can be used, which may be performed maskless. The direct-write system may comprise a digital light processing (DLP) chip, laser galvanometer, etc., that projects a pattern as one image or as a scan. In FIG. 2C, a direct-write projection tool 245 is illustrated. In another embodiment (not illustrated), a mask-based lithographic exposure using a scanner or stepper tool may be used. Although direct-write tools have lower resolution than mask-based tools, the resolution needed to fine tune stress can be much lower as compared to patterning transistors. Also, a stress map created with a mask can be static, whereas using a direct-write tool can be dynamic so a stress map can be created or projected and changed on a wafer-by-wafer basis if desired.

In certain embodiments, this first exposure step may use a visible light to excite a visible light responsive photo initiator to induce crosslinking for polymerization. The crosslinking may be, for example, thiol-yne reaction but other reactions may be employed. Wavelength can be dependent on components included in a given stress film. For example, the wavelength for the exposure step may be 400 nm or longer, and in one embodiment, between 400 nm and 600 nm. In various embodiments, a photo initiator such as HABI-based initiator having an absorption tail in the range of 400-470 nm may be used. Embodiments herein can also include using multiple films that respond to different wavelengths of light. The type of additives (e.g., photo initiator) to include may be selected in view of their absorption characteristic so that the first and second actinic radiation exposures can induce different reactions in the polymer network.

This exposure step may be executed within a direct write module on the coater-developer tool or be transferred to a separate or connected tool for exposure. The actinic radiation can be patterned wherein more or less radiation is received at coordinate locations on the backside surface 215 of the substrate 200. Resolution can be dependent on a particular lithography system selected for executing the exposure. Location-dependent dose of the actinic radiation may enable a variation in the degree of chemical responses (e.g., crosslinking) in the stressed film 235, as illustrated in FIG. 2C as gray gradient.

In one or more embodiments, after the first exposure step and prior to a second exposure step (FIG. 2D), a post exposure bake may be performed. Further, an optical curing step may also be performed. In various embodiments, these steps may be performed in a bake/curing module of the coater developer tool.

In certain embodiments, the direct write programmable pattern may essentially activate (or pre-activate) stress through cross-linking or chemical transformation that is activated by a particular wavelength of light or electromagnetic energy that can include longer wavelengths in the infrared (IR) or thermal regions. The IR wavelengths can be used to pattern the tunable stress film 225. In some embodiments, the tunable stress film 225, particularly when formed on the backside surface 215, may be activated using a wafer chuck with spatial temperature control either in the track device or in the device fabrication equipment. Stress activation can be tailored using different wavelengths of light based on additives to the tunable stress film 225.

In certain embodiments, the exposure step may use a blanket exposure to uniformly treat the entire surface of the tunable stress film 225. As a result, there may be no local variation in bow mitigation capability across the stressed film 235, while the stressed film 235 may uniformly improve the stiffness of the substrate 200 and thereby improve the resistance to wafer bow during subsequent fabrication processes. In one or more embodiments, the local variation in bow mitigation capability may advantageously be introduced later, for example, by a second exposure step for rearrangement.

FIG. 2D illustrates the substrate during an exposure to a pattern of a second actinic radiation.

In various embodiments, the stressed film 235 of FIG. 2C may be further exposed to a pattern of a second actinic radiation 260 to induce another chemical reaction such as rearrangement to modify the level of bow mitigation globally or locally. The stress film exposed to the second actinic radiation is herein referred to as a relaxed film 255 to indicate some relaxation of the built up stress that was present in the stressed film 235 in FIG. 2C. This second pattern of actinic radiation may define a second stress modification pattern for the film. In certain embodiments, the first exposure step may cause a global bow correction and the second exposure step may cause a local bow correction.

In FIG. 2D, the pattern of the second actinic radiation 260 may be selected to expose only a portion 265 of the stressed film. In other embodiments, however, a blanket exposure may be used to treat the stressed film 235 uniformly.

In FIG. 3C, the effect of the second exposure step is illustrated in the simple bow test continued from FIG. 3B. The substrate 200 having the stressed film 235 (FIG. 3B) may be exposed to the pattern of the second actinic radiation for rearrangement to form a relaxed film 255 (FIG. 3C). The rearrangement may induce a secondary structural change in the film causing the film to relax the force previously generated during the first exposure step, resulting in a weakened force indicated by arrows in FIG. 3C. As a result of this stress release, the bow of the substrate 200 in FIG. 3B may be relaxed. As illustrated in FIG. 3C, in various embodiments, the stress release due to the rearrangement may still leave some residual stress built in the film such that the substrate 200 may still have a bow, although it is smaller than prior to the second exposure step. This stress release effect of the second exposure step can provide the methods of bow mitigation with a stress film with a certain level of reversibility, and may also improve the tunability of a stress film. Controlling the chemical composition of the stress film and doses of each of the exposure steps, it is possible to achieve a desired level of stress from the stress film within a range including a neutral state (FIG. 3A), a stressed state (FIG. 3B), and a relaxed state (FIG. 3C).

In other embodiments, the two actinic radiation exposure steps may be both used to induce crosslinking but to a different degree, rather than rearrangement. In this case, the first exposure step (e.g., visible light) may lead to an only partial crosslinking, and the second exposure step (e.g., UV light) may cause further crosslinking. Such an embodiment may advantageously enable step-wise crosslinking of the polymer network. One representative example is further described referring to FIGS. 8A and 8B below.

In various embodiments, a similar or same tool as the one for the first exposure step may be used. In various embodiments, a direct-write laser or lithography tool can be used. In another embodiment, a mask-based lithographic exposure using a scanner or stepper tool may be used. In certain embodiments, an ultraviolet (UV) light may be used for the second actinic radiation. In one embodiment, the wavelength of light (i.e., the actinic radiation) may be 365 nm, but other wavelengths may be used in other embodiments.

In one or more embodiments, after the second exposure step, a post exposure bake may be performed. Further, an optical curing step may also be performed.

FIG. 4 illustrates an example alkyne used as a monomer for stress film formation in accordance with an embodiment.

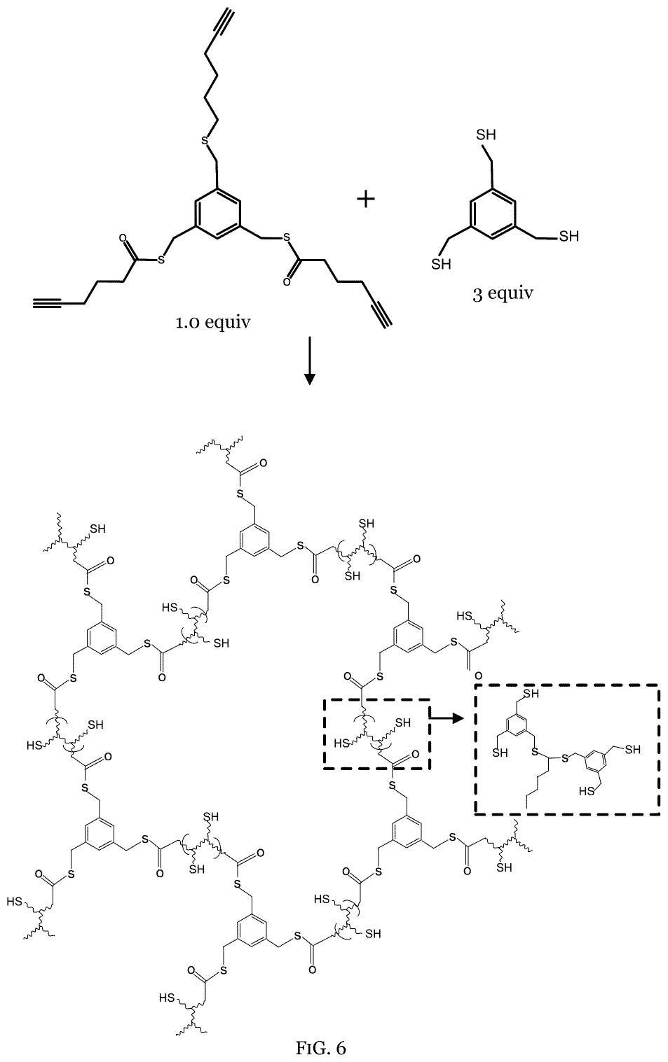

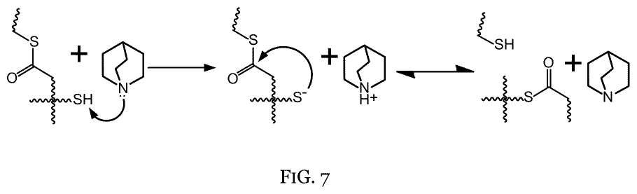

In various embodiments, an alkyne may be used as a first type of monomer for polymer synthesis in forming a tunable stress film. In certain embodiments, alkyne functional thio-ester building blocks may be used. In FIG. 4, a molecular structure of an example tri-alkyne functional aromatic core building block is illustrated. This particular structure may be derived from 1,3,5-trithiomethyl benzene (TTMB), using the 1-ethyl-3-(3-dimethylaminopropyl) carbodiimide hydrochloride (EDC) coupling reaction. In other embodiments, the alkyne may have an aliphatic core structure instead of an aromatic one. The use of alkyne may enable a photo-initiated crosslinking reaction such as thio-yne reaction (FIG. 6). In certain embodiments, each alkyne monomer may comprise at least two alkynyl groups (three alkynyl groups in FIG. 4) in order to facilitate crosslinking, but it may comprise only one alkynyl group in other embodiments. Having the thioester structure in the building block as illustrated in FIG. 4 may advantageously enable a rearrangement mechanism (e.g., thiol-thioester exchange reaction, FIG. 7). The structure of the monomer building block may be determined in consideration of factors including but not limited to the reactivity, bulkiness, cost, the resulting polymer characteristics, and monomer availability.

FIG. 5 illustrates an example thiol used for a bow mitigation stress film in accordance with an embodiment.

In various embodiments, a thiol may be used as a second type of monomer for polymer synthesis in forming a tunable stress film. In certain embodiments, 1,3,5-trithiomethyl benzene (TTMB) may be used as illustrated in FIG. 5. TTMB may be derived from 1,3,5-tribromomethyl benzene via thiolation using, for example, thioacetic acid. In other embodiments, the thiol may have an aliphatic structure instead of an aromatic one. The use of thiol may enable a photo-initiated crosslinking reaction such as thio-yne reaction (FIG. 6). In certain embodiments, each thiol monomer may comprise at least two thiol groups (three thiol groups in FIG. 5) in order to facilitate crosslinking, but it may comprise only one thiol group in other embodiments. The structure of the monomer building block may be determined in consideration of factors including but not limited to the reactivity, bulkiness, cost, the resulting polymer characteristics, and monomer availability.

FIG. 6 illustrates a formation of an example bow mitigation stress film via thiol-yne reaction in accordance with an embodiment.

In FIG. 6, an example thiol-yne reaction for crosslinking the alkyne (the monomer illustrated in FIG. 4) and the thiol (the monomer illustrated in FIG. 5) is illustrated. The crosslinked structure may be able to exert a bending force on a substrate, and the bending force may be used to bow the substrate or reduce an existing bow of the substrate. The thiol-yne reaction may be initiated by an exposure to an actinic radiation (such as the first actinic radiation 250 illustrated in FIG. 2C) with the aid of a photo initiator. Accordingly, the film precursor may comprise such an additive in addition to the monomers. In certain embodiments, a free radical photo initiator based on the hexaaryl-bisimidazolyl (HABI) molecule that may be activated by a visible light may be used. In another embodiment, 2,2-Dimethoxy-2-phenylacetophenone (DMPA) that may be activated by an UV light may be used.

As illustrated in FIG. 6, the crosslinked structure has a thioester structure, and also still comprise residual thiol groups. In various embodiments, due to the presence of both thioesters and thiols in the structure, a rearrangement of the structure via thiol-thioester exchange reaction is possible (FIG. 7).

Although various embodiments of this disclosure describe thiol-yne reaction for crosslinking, other polymerization schemes may be used in other embodiments. In one embodiment, thiol-ene reaction may be used to react thiol and alkene.

FIG. 7 illustrates a mechanism of an example rearrangement of a polymer structure for a bow mitigation stress film.

In FIG. 7, a base-catalyzed mechanism of an example rearrangement via thiol-thioester exchange reaction is illustrated. Quinuclidine is illustrated as the base catalyst in FIG. 7. The base catalyst may activate a sulfur atom of a thiol group of the polymer network by deprotonation (left in FIG. 7), and the formed S⁻ may attack the thioester to cleave the C—S bond (middle in FIG. 7). The S⁻ may then form a new thioester, leaving a new thiol group (right in FIG. 7). Accordingly, the exchange reaction does not change the overall number of thiol and thioester groups, making it only a rearrangement. This mechanism of rearrangement is advantageous in maintaining the overall polymer structure causing little to no loss of the film through disintegration, while the stress built up during the crosslinking may be at least partially released. Therefore, this stress release may be used to further tune the bow mitigation capability (e.g., FIG. 3C).

In various embodiments, 2-(2-nitrophenyl)-propyloxycarbonyl/tetramethylguanidine (NPPOC-TMG) may be used as a photo-base that can be activated by a UV light (e.g., 365 nm). The photo-base may be selected such that it is stable under the first actinic radiation during crosslinking (e.g., visible light) and responsive to the second actinic radiation (e.g., UV light).

Further, although not wishing to be limited by any theory, in certain embodiments, the kinetic of the rearrangement may depend on the molecular structure of the polymer network for the stress film, and the stress release by rearrangement in polymer network with an aromatic core structure may advantageously be at least twice as fast as that with an aliphatic core structure.

FIGS. 8A-8C illustrate experimental results for bow mitigation with tuning ability in accordance with an embodiment.

The inventors of this application conducted experiments to examine the tunability of an example thiol-thioester based polymer stress film. The stress film with the aromatic core structure in FIG. 6 was prepared for the test and spin-coated on a substrate. In FIG. 8A, a surface height profile of a substrate with a spin-on stress film after a visible light exposure is illustrated with a reference of a bare Si wafer. In this example, the visible light exposure led to a partial crosslinking. Subsequently, the same substrate with the spin-on stress film was exposed to an UV light. In FIG. 8B, further crosslinking proceeds and the UV-induced stress results in the bent structure of the substrate. Further, after this second exposure, the substrate was further treated with a base vapor, tetramethylguanidine (TMG), to examine the base-induced rearrangement for stress relaxation (FIG. 8C). In FIG. 8C, the substrate is bent to a lesser extent relative to FIG. 8B, but still more than FIG. 8A. This result confirms the stress release is possible via the base-catalyzed rearrangement of the crosslinked thiol-thioester polymer system.

FIGS. 9A-9C illustrate process flow charts of methods of forming a stress film in accordance with various embodiments. The process flow can be followed with the figures (FIGS. 2B-2D) discussed above and hence will not be described again.

In FIG. 9A, a process flow 90 starts with depositing first and second monomers over a substrate (block 910, FIG. 2B), followed by exposing the substrate to a first actinic radiation to induce a polymerization that forms a polymer film from the first and second monomers over the substrate (block 920, FIG. 2C). After forming the polymer film, the substrate may have a bow with a first curvature. Subsequently, the substrate may be exposed to a second actinic radiation to induce a rearrangement of the polymer film (block 930, FIG. 2D). The rearrangement may reduce the bow.

In FIG. 9B, another process flow 92 starts with spin coating a film over a backside surface of a substrate comprising a major working surface having a semiconductor device structure and the backside surface opposite the major working surface (block 912, FIG. 2B). Prior to the spin coating, the substrate has an initial bow with a first curvature. Next, the backside surface of the substrate may be exposed to a pattern of a first actinic radiation (block 922, FIG. 2C), followed by exposing the backside surface of the substrate to a pattern of a second actinic radiation with a wavelength shorter than that of the first actinic radiation (block 932, FIG. 2D). After the exposure to the pattern of the second actinic radiation, the substrate has a bow with a second curvature less than the first curvature.

In FIG. 9C, another process flow 94 starts with depositing a film comprising an alkyne and a thiol over the substrate (block 914, FIG. 2B) Prior to depositing the film, the substrate has an initial bow with a first curvature. Subsequently, the film may be polymerized via a thiol-yne reaction to form a polymer by exposing the substrate to a pattern of visible light (block 924, FIG. 2C). After polymerizing the film, the substrate has an intermediate bow with a second curvature different from the first curvature. A portion of the polymer may then be rearranged via a thiol-thioester exchange reaction by exposing the substrate to a pattern of ultraviolet (UV) light, reducing the intermediate bow (block 934, FIG. 2D).

FIG. 10 illustrate a block diagram of an example coater system 1000 for stress film formation in accordance with an embodiment.

The coater system 1000 is just one example of a coater-developer system that may be used with certain embodiments of this disclosure. In the illustrated example, the coater system 1000 includes a track system 1002 and a projection system 1004. The track system 1002 includes a series of process modules assembled to allow potentially sequential execution of processes for the process being performed using the coater system 1000. The track system 1002 provides the material processes such as coating the wafer with a photoresist for a lithographic process, baking the photoresist (potentially more than once), and developing the photoresist.

In the illustrated example, the process modules of the track system 1002 include a first spin-coating module 1006 (e.g., for depositing the photoresist), a first bake module 1008, a second spin-coating module 1010 (e.g., for depositing the stress film or film precursor), a second bake module 1012 (e.g., for promoting crosslinking in the photoresist), a third bake module 1014 (e.g., for causing crosslinking in the stress film), and a developing module 1016 for developing the photoresist.

The coater system 1000 may include a transfer system to move a substrate from module-to-module of the track system 1002, as well as from the track system 1002 to the projection system 1004 (which may be considered “off track”) and from the projection system 1004 back to the track system 1002. In various embodiments, the projection system 1004 may be a direct-write projection tool or a projection scanner configured to perform an exposure step for the stress film.

Example embodiments of the invention are summarized here. Other embodiments can also be understood from the entirety of the specification as well as the claims filed herein.

Example 1. A method of processing a substrate that includes: depositing first and second monomers over a substrate, the first monomer being a first type of monomer and the second monomer being a second type of monomer different from the first type of monomer; exposing the substrate to a first actinic radiation to induce a polymerization that forms a polymer film from the first and second monomers over the substrate, where, after forming the polymer film, the substrate has a bow with a first curvature; and exposing the substrate to a second actinic radiation to induce a rearrangement of the polymer film, the rearrangement reducing the bow.

Example 2. The method of example 1, where the depositing is performed using a spin-on process.

Example 3. The method of one of examples 1 or 2, where, prior to the depositing, the substrate has a bow with an initial curvature greater than the first curvature.

Example 4. The method of one of examples 1 to 3, where, after the rearrangement, the substrate has a bow with a second curvature less than the first curvature.

Example 5. The method of one of examples 1 to 4, where the first monomer includes an alkyne, where the second monomer includes a thiol, and where the polymerization is a thiol-yne reaction.

Example 6. The method of one of examples 1 to 5, where the polymer film includes thiol functional groups, and where the rearrangement is a thiol-thioester exchange reaction.

Example 7. The method of one of examples 1 to 6, where the first actinic radiation is a visible light and the second actinic radiation is an ultraviolet (UV) light.

Example 8. The method of one of examples 1 to 7, where the polymer film includes a photo-base, where the photo-base releases a base in the film by the exposure to the second actinic radiation, and where the generated base catalyzes the rearrangement.

Example 9. A method of processing a substrate that includes: spin coating a film over a substrate including a major working surface having a semiconductor device structure and a backside surface opposite the major working surface, the film being coated over the backside surface, where, prior to the spin coating, the substrate has an initial bow with a first curvature; exposing the backside surface of the substrate to a pattern of a first actinic radiation; and after the exposure to the pattern of the first actinic radiation, exposing the backside surface of the substrate to a pattern of a second actinic radiation with a wavelength shorter than that of the first actinic radiation, where, after the exposure to the pattern of the second actinic radiation, the substrate has a bow with a second curvature less than the first curvature.

Example 10. The method of example 9, where the pattern of the first actinic radiation or the pattern of the second actinic radiation is provided by a direct write lithography system.

Example 11. The method of one of example 9, where the pattern of the first actinic radiation or the pattern of the second actinic radiation is provided by a mask-based lithography system.

Example 12. The method of one of examples 9 to 11, where the exposure to the first actinic radiation causes a polymerization in the film to form a polymer, and where the exposure to the second actinic radiation causes a rearrangement of the polymer.

Example 13. The method of one of examples 9 to 12, further including, prior to the spin-coating, performing a wafer bow measurement to obtain spatial information of the initial bow of the substrate.

Example 14. The method of one of examples 9 to 13, further including, determining the patterns of the first and second actinic radiations based on the spatial information of the initial bow of the substrate.

Example 15. The method of one of examples 9 to 14, further including, after the exposure to the pattern of the first actinic radiation, performing a bow measurement to obtain spatial information of an intermediate bow of the substrate; and determining the pattern of the second actinic radiation based on the spatial information of the intermediate bow of the substrate.

Example 16. A method of processing a substrate that includes: depositing a film over a substrate, the film including an alkyne and a thiol, where, prior to depositing the film, the substrate has an initial bow with a first curvature; polymerizing the film via a thiol-yne reaction to form a polymer by exposing the substrate to a pattern of visible light, where, after polymerizing the film, the substrate has an intermediate bow with a second curvature different from the first curvature; and rearranging a portion of the polymer via a thiol-thioester exchange reaction by exposing the substrate to a pattern of ultraviolet (UV) light, the rearranging the portion of the polymer reducing the intermediate bow.

Example 17. The method of example 16, where the polymerizing and the rearranging are performed using a direct write lithography system.

Example 18. The method of one of examples 16 or 17, where the alkyne is a thioester having an aromatic core.

Example 19. The method of one of examples 16 to 18, where the thiol is 1,3,5-trithiomethyl benzene (TTMB).

Example 20. The method of one of examples 16 to 19, where the film is deposited by a spin-on process using propylene glycol methyl ether acetate (PGMEA) as a solvent.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of processing a substrate, the method comprising:
depositing first and second monomers over a substrate, the first monomer being a first type of monomer and the second monomer being a second type of monomer different from the first type of monomer;
exposing the substrate to a first actinic radiation to induce a polymerization of the first and second monomers over the substrate, wherein, after the polymerization, the substrate has a bow with a first curvature; and
exposing the substrate to a second actinic radiation to induce a rearrangement of the polymer, the rearrangement reducing the bow.

2. The method of claim 1, wherein the depositing is performed using a spin-on process.

3. The method of claim 1, wherein, prior to the depositing, the substrate has a bow with an initial curvature greater than the first curvature.

4. The method of claim 1, wherein, after the rearrangement, the substrate has a bow with a second curvature less than the first curvature.

5. The method of claim 1, wherein the first monomer comprises an alkyne, wherein the second monomer comprises a thiol, and wherein the polymerization is a thiol-yne reaction.

6. The method of claim 4, wherein the polymer comprises thiol functional groups, and wherein the rearrangement is a thiol-thioester exchange reaction.

7. The method of claim 1, wherein the first actinic radiation is a visible light and the second actinic radiation is an ultraviolet (UV) light.

8. The method of claim 1, wherein the polymer comprises a photo-base, wherein the photo-base releases a base by the exposure to the second actinic radiation, and wherein the generated base catalyzes the rearrangement.

9. A method of processing a substrate, the method comprising:
spin coating a film over a substrate comprising a major working surface having a semiconductor device structure and a backside surface opposite the major working surface, the film being coated over the backside surface, wherein, prior to the spin coating, the substrate has an initial bow with a first curvature;
exposing the backside surface of the substrate to a pattern of a first actinic radiation; and
after the exposure to the pattern of the first actinic radiation, exposing the backside surface of the substrate to a pattern of a second actinic radiation with a wavelength shorter than that of the first actinic radiation,
wherein, after the exposure to the pattern of the second actinic radiation, the substrate has a bow with a second curvature less than the first curvature.

10. The method of claim 9, wherein the pattern of the first actinic radiation or the pattern of the second actinic radiation is provided by a direct write lithography system.

11. The method of claim 9, wherein the pattern of the first actinic radiation or the pattern of the second actinic radiation is provided by a mask-based lithography system.

12. The method of claim 9, wherein the exposure to the first actinic radiation causes a polymerization in the film to form a polymer, and wherein the exposure to the second actinic radiation causes a rearrangement of the polymer.

13. The method of claim 9, further comprising, prior to the spin-coating, performing a wafer bow measurement to obtain spatial information of the initial bow of the substrate.

14. The method of claim 13, further comprising, determining the patterns of the first and second actinic radiations based on the spatial information of the initial bow of the substrate.

15. The method of claim 9, further comprising,
after the exposure to the pattern of the first actinic radiation, performing a bow measurement to obtain spatial information of an intermediate bow of the substrate; and
determining the pattern of the second actinic radiation based on the spatial information of the intermediate bow of the substrate.

16. A method of processing a substrate, the method comprising:
depositing a film over a substrate, the film comprising an alkyne and a thiol, wherein, prior to depositing the film, the substrate has an initial bow with a first curvature;
polymerizing the film via a thiol-yne reaction to form a polymer by exposing the substrate to a pattern of visible light, wherein, after polymerizing the film, the substrate has an intermediate bow with a second curvature different from the first curvature; and
rearranging a portion of the polymer via a thiol-thioester exchange reaction by exposing the substrate to a pattern of ultraviolet (UV) light, the rearranging the portion of the polymer reducing the intermediate bow.

17. The method of claim 16, wherein the polymerizing and the rearranging are performed using a direct write lithography system.

18. The method of claim 16, wherein the alkyne is a thioester having an aromatic core.

19. The method of claim 16, wherein the thiol is 1,3,5-trithiomethyl benzene (TTMB).

20. The method of claim 16, wherein the film is deposited by a spin-on process using propylene glycol methyl ether acetate (PGMEA) as a solvent.
